(19) United States
(12) Patent Application Publication
(10) Pub. No.: US 2025/0324620 A1
(43) Pub. Date: Oct. 16, 2025

(54) TRENCH CAPACITOR AND FABRICATION METHOD THEREOF

(71) Applicant: UNITED MICROELECTRONICS CORP., Hsin-Chu City (TW)

(72) Inventors: Po-Kuang Hsieh, Kaohsiung City (TW); Ssu-I Fu, Kaohsiung City (TW); Chun-Ya Chiu, Tainan City (TW); Chin-Hung Chen, Tainan City (TW); Yu-Hsiang Lin, New Taipei City (TW)

(73) Assignee: UNITED MICROELECTRONICS CORP., Hsin-Chu City (TW)

(21) Appl. No.: 18/675,116

(22) Filed: May 27, 2024

(30) Foreign Application Priority Data
Apr. 16, 2024 (TW) 113114070

(51) Int. Cl. H10D 1/00; H10D 1/68

(52) U.S. Cl. CPC H10D 1/042; H10D 1/716

(57) ABSTRACT

A trench capacitor includes a semiconductor substrate having upwardly protruding structures and first trenches between the upwardly protruding structures. Each upwardly protruding structure has an enlarged head portion and a body portion. A dielectric template layer covers the upwardly protruding structures and bottom surfaces of the first trenches. An outer surface of the dielectric template layer defines second trenches between the upwardly protruding structures. Each second trench has a widened lower portion, a shrunk upper portion, and a middle portion between the widened lower portion and the shrunk upper portion. A capacitor film stack covers the dielectric template layer. A sealing layer covers the capacitor film stack. The sealing layer seals the second trench at the shrunk upper portion, thereby forming stress-releasing voids between the upwardly protruding structures.

### BACKGROUND OF THE INVENTION

### 1. Field of the Invention

The present invention relates to the field of semiconductor technology, and in particular, to a trench capacitor and a manufacturing method thereof.

### 2. Description of the Prior Art

As known in the art, a trench capacitor is a three-dimensional device formed by etching a trench into a semiconductor substrate. Many of the processes used in the fabrication of silicon integrated circuits lead to the development of stress in the silicon substrate. Given enough stress, the substrate will yield by generating stress-induced defects, which may affect the performance of the trench capacitor.

Therefore, this technical field still needs an improved trench capacitor and a manufacturing method to solve the above problems.

### SUMMARY OF THE INVENTION

It is one object of the present invention to provide an improved trench capacitor and a manufacturing method thereof in order to solve the deficiencies or shortcomings of the existing technology.

One aspect of the invention provides a trench capacitor including a semiconductor substrate comprising upwardly protruding structures and first trenches between the upwardly protruding structures, wherein each of the upwardly protruding structures has an enlarged head portion and a body portion under the enlarged head portion, wherein the enlarged head portion has a dimension that is greater than a dimension of the body portion; a dielectric template layer covering the upwardly protruding structures and bottom surfaces of the first trenches, wherein an outer surface of the dielectric template layer defines second trenches between the upwardly protruding structures, wherein each of the second trenches has a widened lower portion, a shrunk upper portion, and a middle portion between the widened lower portion and the shrunk upper portion; a capacitor film stack conformally covering the dielectric template layer; and a sealing layer conformally covering the capacitor film stack, wherein the sealing layer seals each of the second trenches at the shrunk upper portion, thereby forming stress-releasing voids between the upwardly protruding structures.

According to some embodiments, the enlarged head portion has a hexagonal outline.

According to some embodiments, the semiconductor substrate is a silicon substrate, and wherein the upwardly protruding structures comprise silicon.

According to some embodiments, a bottom surface of each of the first trenches has a concave profile.

According to some embodiments, the dielectric template layer comprises silicon oxide.

According to some embodiments, the dielectric template layer has a thickness of 100-200 angstroms.

According to some embodiments, the capacitor film stack comprises a metal-oxide-metal (MIM) film stack.

According to some embodiments, the MIM film stack comprises a first electrode layer, a capacitor layer on the first electrode layer, and a second electrode layer on the capacitor layer.

According to some embodiments, the first electrode layer comprises titanium nitride, the capacitor layer comprises zirconium oxide, aluminum oxide, or a combination thereof, and the second electrode layer comprises titanium nitride.

According to some embodiments, the sealing layer comprises silicon oxide.

Another aspect of the invention provides a method for forming a trench capacitor. A semiconductor substrate comprising upwardly protruding structures and first trenches between the upwardly protruding structures is provided. Each of the upwardly protruding structures has an enlarged head portion and a body portion under the enlarged head portion. The enlarged head portion has a dimension that is greater than a dimension of the body portion. A dielectric template layer is formed. The dielectric template covers the upwardly protruding structures and bottom surfaces the first trenches. An outer surface of the dielectric template layer defines second trenches between upwardly protruding structures. Each of the second trenches has a widened lower portion, a shrunk upper portion, and a middle portion between the widened lower portion and the shrunk upper portion. A capacitor film stack is formed on the dielectric template layer. A sealing layer is formed on the capacitor film stack. The sealing layer seals each of the second trenches at the shrunk upper portion, thereby forming stress-releasing voids between the upwardly protruding structures.

According to some embodiments, the enlarged head portion has a hexagonal outline.

According to some embodiments, the semiconductor substrate is a silicon substrate, and wherein the upwardly protruding structures comprise silicon.

According to some embodiments, a bottom surface of each of the first trenches has a concave profile.

According to some embodiments, the dielectric template layer comprises silicon oxide.

According to some embodiments, the dielectric template layer has a thickness of 100-200 angstroms.

According to some embodiments, the capacitor film stack comprises a metal-oxide-metal (MIM) film stack.

According to some embodiments, the MIM film stack comprises a first electrode layer, a capacitor layer on the first electrode layer, and a second electrode layer on the capacitor layer.

According to some embodiments, the first electrode layer comprises titanium nitride, the capacitor layer comprises zirconium oxide, aluminum oxide, or a combination thereof, and the second electrode layer comprises titanium nitride.

According to some embodiments, the sealing layer comprises silicon oxide.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 to FIG. 5 are schematic diagrams of a method of forming a trench capacitor according to an embodiment of the present invention.

### DETAILED DESCRIPTION

In the following detailed description of the disclosure, reference is made to the accompanying drawings, which form a part hereof, and in which is shown, by way of illustration, specific embodiments in which the invention may be practiced. These embodiments are described in sufficient detail to enable those skilled in the art to practice the invention.

Other embodiments may be utilized, and structural, logical, and electrical changes may be made without departing from the scope of the present invention. Therefore, the following detailed description is not to be considered as limiting, but the embodiments included herein are defined by the scope of the accompanying claims.

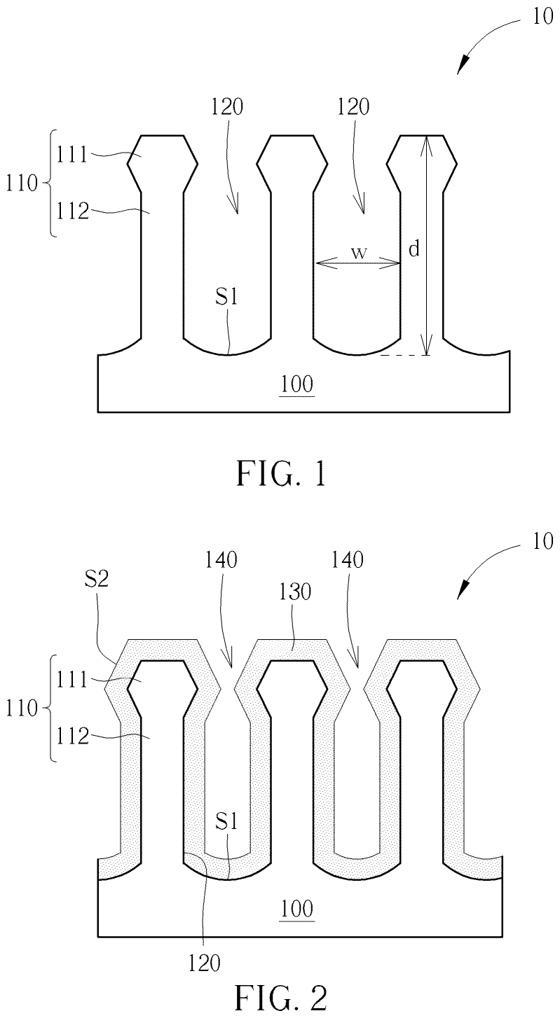

Please refer to FIGS. 1 to 5, which are schematic diagrams of a method of forming a trench capacitor 10 according to an embodiment of the present invention. As shown in FIG. 1, a semiconductor substrate 100 is provided, which includes multiple upwardly protruding structures 110 and first trenches 120 between the upwardly protruding structures 110. According to an embodiment of the present invention, the semiconductor substrate 100 may be, for example, a silicon substrate, and the upwardly protruding structure 110 includes silicon. According to an embodiment of the present invention, the first trench 120 is a deep trench, with a depth d of approximately 6-9 micrometers and a width w of approximately 0.2-0.3 micrometers. According to an embodiment of the present invention, the bottom surface S1 of the first trench 120 has an arc-shaped concave profile.

According to an embodiment of the present invention, the upward protruding structure 110 has an enlarged head portion 111 and a body portion 112 below the enlarged head portion 111, wherein the size (cross-sectional width) of the enlarged head portion 111 is larger than the size (cross-sectional width) of the body portion 112. According to an embodiment of the invention, the enlarged head portion 111 has a hexagonal outline.

As shown in FIG. 2, an atomic layer deposition (ALD) process is then performed to deposit a dielectric template layer 130 on the semiconductor substrate 100 in a blanket manner so that the dielectric template layer 130 conformally covers the upward protruding structure 110 and the bottom surface S1 of the first trench 120. According to an embodiment of the present invention, for example, the dielectric template layer 130 may include silicon oxide, but is not limited thereto. According to an embodiment of the present invention, the thickness of the dielectric template layer 130 may be, for example, 100-200 angstroms. According to an embodiment of the present invention, the outer surface S2 of the dielectric template layer 140 defines a second trench 140 between the upwardly protruding structures 110. At this point, the profile of the second trench 140 is similar to the profile of the first trench 120.

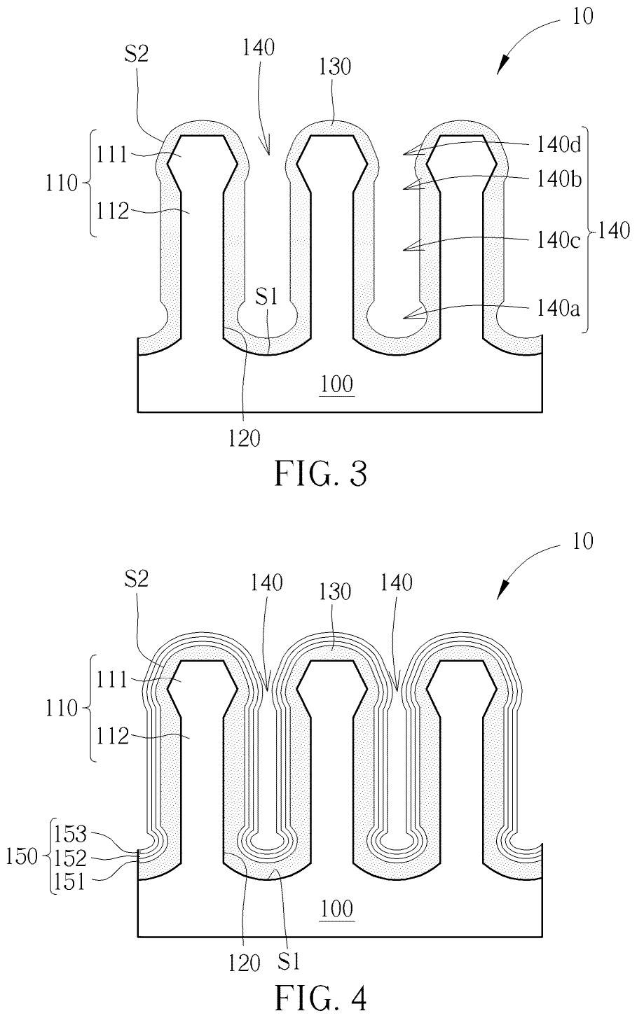

As shown in FIG. 3, an etching process, such as a dry etching process and a wet etching process, is then performed to thin the dielectric template layer 130 and trim the profile of the second trench 140 to a bottle-shaped profile. According to an embodiment of the present invention, the second trench 140 has a widened lower portion 140a, a shrunk upper portion 140b, and a middle portion 140c located between the widened lower portion 140a and the shrunk upper portion 140b. According to an embodiment of the present invention, the uppermost part of the second trench 140 may be the tapered upper portion 140d, which is directly connected to the shrunk upper portion 140b. According to an embodiment of the present invention, the widened lower portion 140a of the second trench 140 has the largest width. According to an embodiment of the present invention, for example, the above-mentioned wet etching process may include etching the dielectric template layer 130 using SPM (H₂SO₄/H₂O₂/H₂O) solution and SC1 (NH₄OH/H₂O₂/H₂O) solution.

As shown in FIG. 4, a deposition process is then performed to form a capacitor film stack 150 conformally on the dielectric template layer 130. According to an embodiment of the present invention, the capacitive film stack 150 includes, for example, a metal-oxide-metal (MIM) film stack. According to an embodiment of the present invention, the MIM film stack may include a first electrode layer 151, a capacitor layer 152 on the first electrode layer 151, and a second electrode layer 153 on the capacitor layer 152. According to an embodiment of the present invention, the first electrode layer 151 includes, for example, titanium nitride, the capacitor layer 152 includes, for example, zirconium oxide, aluminum oxide or a combination thereof, and the second electrode layer 153 includes, for example, titanium nitride. At this point, the capacitor film stack 150 filled into the second trench 140 does not seal the second trench 140 at the shrunk upper portion 140b of the second trench 140.

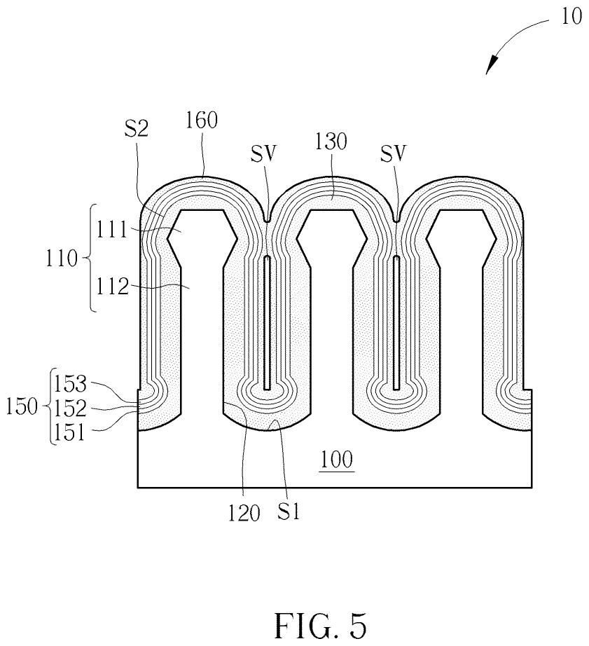

As shown in FIG. 5, the ALD process is then performed to conformally deposit a sealing layer 160 on the capacitor film stack 150. According to an embodiment of the present invention, the sealing layer 160 includes silicon oxide, for example. According to an embodiment of the present invention, the sealing layer 160 seals the second trench 140 at the shrunk upper portion 140b of the second trench 140 and forms a stress-releasing void SV between the upwardly protruding structures 110. The stress-releasing void SV can prevent defects caused by stress generated in the semiconductor substrate 100 from affecting the performance of the trench capacitor 10.

Structurally, as shown in FIG. 3 to FIG. 5, the trench capacitor 10 of the present invention includes: a semiconductor substrate 100 including upwardly protruding structures 110 and first trenches 120 between the upwardly protruding structures 110, wherein each of the upwardly protruding structures 110 has an enlarged head portion 111 and a body portion 112 located below the enlarged head portion 111, wherein the size of the enlarged head portion 111 is greater than the size of the body portion 112; a dielectric template layer 130 covering the upwardly protruding structure 110 and a bottom surface SI of the first trench 120, wherein the outer surface S2 of the dielectric template layer 130 defines a second trench 140 between the upwardly protruding structures 110, wherein cach second trench 140 has a widened lower portion 140a, a shrunk upper portion 140b, and a middle portion 140c between the widened lower portion 140a and the shrunk upper portion 140b; a capacitor film stack 150 conformably covering the dielectric template layer 130; and a sealing layer 160 conformably covering the capacitor film stack Layer 150. The sealing layer 160 seals cach second trench 140 at the shrunk upper portion 140b, and forms a stress-releasing void SV between the upwardly protruding structures 110.

According to an embodiment of the present invention, the semiconductor substrate 100 is a silicon substrate, and the upwardly protruding structure 110 includes silicon. According to an embodiment of the invention, the enlarged head portion 111 has a hexagonal outline.

According to an embodiment of the present invention, the bottom surface S1 of the first trench 120 has a concave profile.

According to an embodiment of the invention, the dielectric template layer 130 includes silicon oxide. According to an embodiment of the present invention, the thickness of the dielectric template layer 130 is 100-200 angstroms.

According to an embodiment of the present invention, the capacitive film stack 150 includes a metal-oxide-metal (MIM) film stack. According to an embodiment of the present invention, the MIM film stack includes a first electrode layer 151, a capacitor layer 152 on the first electrode layer 151, and a second electrode layer 153 on the capacitor layer 152. According to an embodiment of the present invention, the first electrode layer 151 includes titanium nitride, the capacitor layer 152 includes zirconium oxide, aluminum oxide or a combination thereof, and the second electrode layer 153 includes titanium nitride.

According to an embodiment of the present invention, the sealing layer 160 includes silicon oxide.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A trench capacitor, comprising:
a semiconductor substrate comprising upwardly protruding structures and first trenches between the upwardly protruding structures, wherein each of the upwardly protruding structures has an enlarged head portion and a body portion under the enlarged head portion, wherein the enlarged head portion has a dimension that is greater than a dimension of the body portion;
a dielectric template layer covering the upwardly protruding structures and bottom surfaces of the first trenches, wherein an outer surface of the dielectric template layer defines second trenches between the upwardly protruding structures, wherein each of the second trenches has a widened lower portion, a shrunk upper portion, and a middle portion between the widened lower portion and the shrunk upper portion;
a capacitor film stack conformally covering the dielectric template layer; and
a sealing layer conformally covering the capacitor film stack, wherein the sealing layer seals each of the second trenches at the shrunk upper portion, thereby forming stress-releasing voids between the upwardly protruding structures.

2. The trench capacitor according to claim 1, wherein the enlarged head portion has a hexagonal outline.

3. The trench capacitor according to claim 1, wherein the semiconductor substrate is a silicon substrate, and wherein the upwardly protruding structures comprise silicon.

4. The trench capacitor according to claim 1, wherein a bottom surface of each of the first trenches has a concave profile.

5. The trench capacitor according to claim 1, wherein the dielectric template layer comprises silicon oxide.

6. The trench capacitor according to claim 1, wherein the dielectric template layer has a thickness of 100-200 angstroms.

7. The trench capacitor according to claim 1, wherein the capacitor film stack comprises a metal-oxide-metal (MIM) film stack.

8. The trench capacitor according to claim 7, wherein the MIM film stack comprises a first electrode layer, a capacitor layer on the first electrode layer, and a second electrode layer on the capacitor layer.

9. The trench capacitor according to claim 8, wherein the first electrode layer comprises titanium nitride, the capacitor layer comprises zirconium oxide, aluminum oxide, or a combination thereof, and the second electrode layer comprises titanium nitride.

10. The trench capacitor according to claim 1, wherein the sealing layer comprises silicon oxide.

11. A method for forming a trench capacitor, comprising:
providing a semiconductor substrate comprising upwardly protruding structures and first trenches between the upwardly protruding structures, wherein each of the upwardly protruding structures has an enlarged head portion and a body portion under the enlarged head portion, wherein the enlarged head portion has a dimension that is greater than a dimension of the body portion;
forming a dielectric template layer, wherein the dielectric template covers the upwardly protruding structures and bottom surfaces the first trenches, wherein an outer surface of the dielectric template layer defines second trenches between upwardly protruding structures, wherein each of the second trenches has a widened lower portion, a shrunk upper portion, and a middle portion between the widened lower portion and the shrunk upper portion;
forming a capacitor film stack on the dielectric template layer; and
forming a sealing layer on the capacitor film stack, wherein the sealing layer seals each of the second trenches at the shrunk upper portion, thereby forming stress-releasing voids between the upwardly protruding structures.

12. The method according to claim 11, wherein the enlarged head portion has a hexagonal outline.

13. The method according to claim 11, wherein the semiconductor substrate is a silicon substrate, and wherein the upwardly protruding structures comprise silicon.

14. The method according to claim 11, wherein a bottom surface of each of the first trenches has a concave profile.

15. The method according to claim 11, wherein the dielectric template layer comprises silicon oxide.

16. The method according to claim 11, wherein the dielectric template layer has a thickness of 100-200 angstroms.

17. The method according to claim 11, wherein the capacitor film stack comprises a metal-oxide-metal (MIM) film stack.

18. The method according to claim 17, wherein the MIM film stack comprises a first electrode layer, a capacitor layer on the first electrode layer, and a second electrode layer on the capacitor layer.

19. The method according to claim 18, wherein the first electrode layer comprises titanium nitride, the capacitor layer comprises zirconium oxide, aluminum oxide, or a combination thereof, and the second electrode layer comprises titanium nitride.

20. The method according to claim 11, wherein the sealing layer comprises silicon oxide.
